(19) United States
(12) Patent Application Publication
(10) Pub. No.: US 2014/0078810 A1
(43) Pub. Date: Mar. 20, 2014

(54) LOADLESS VOLATILE/NON-VOLATILE MEMORY CELL

(71) Applicants: Guillaume Prenat, Grenoble (FR); Gregory Di Pendina, Echirolles (FR); Kholdoun Torki, Fontaine (FR)

(72) Inventors: Guillaume Prenat, Grenoble (FR); Gregory Di Pendina, Echirolles (FR); Kholdoun Torki, Fontaine (FR)

(73) Assignee: CENTRE NATIONAL DE LA RECHERCHE SCIENTIFIQUE, Paris Cedex 16 (FR)

(21) Appl. No.: 13/980,555

(22) PCT Filed: Jan. 19, 2012
(86) PCT No.: PCT/EP2012/050798

§ 371 Date: Nov. 22, 2013

(30) Foreign Application Priority Data
Jan. 19, 2011 (FR) 1150403

(51) Int. Cl. G11C 13/00

(52) U.S. Cl. CPC G11C 13/0069
USPC 365/148

(57) ABSTRACT

The invention concerns a memory device comprising at least one memory cell comprising: first and second transistors (102, 104) coupled between first and second storage nodes (106, 108) respectively and a first supply voltage, a control terminal of said first transistor being coupled to said second storage node, and a control terminal of said second transistor being coupled to said first storage node; first and second resistance switching elements (202, 204) coupled in series with said first and second transistors respectively; and control circuitry (308) adapted to apply, during a programming phase of the first resistance switching element, a second supply voltage to said second storage node to active said first transistor, and then to apply said second supply voltage to said first storage node to generate a first write current (I_{A}) through said first transistor and said first resistance switching element.

### FIELD OF THE INVENTION

The present invention relates to a programmable volatile/non-volatile memory cell and to a method of writing to the non-volatile portion of such a memory cell.

### BACKGROUND OF THE INVENTION

FIG. 1 illustrates a typical static random access memory (SRAM) cell 100. A first inverter is formed of an N-channel MOS (NMOS) transistor 102 and P-channel MOS (PMOS) transistor 103 coupled in series between a supply voltage V_{DD} and a ground voltage. A second inverter is formed of an NMOS transistor 104 and a PMOS transistor 105 also coupled in series between the supply voltage V_{DD} and the ground voltage. The gates of transistors 104 and 105 are coupled to a node 106 coupled to the drains of transistors 102 and 103, while the gates of transistors 102 and 103 are coupled to a node 108 coupled to the drains of transistors 104 and 105, such that the inverters form a latch.

The nodes 106 and 108 store complementary voltage states Q and Q, permitting one bit of data to be memorized by the cell. Node 106 is coupled to a bit line BL via a P-channel MOS (PMOS) transistor 110, while node 108 is coupled to a complementary bit line BLB via a PMOS transistor 112. The gates of transistors 110 and 112 are coupled to a word line WL, and are activated by a low signal allowing data to be written to or read from the cell 100.

The circuit 100 has the advantage of being relatively quick to access during read and write operations. However, a disadvantage is that, as with all volatile memory cells, the stored data is lost if the supply voltage V_{DD} is removed.

Flash memory is an example of a programmable non-volatile memory. A disadvantage with flash memory is that it is relatively slow to access when compared to the SRAM cell of FIG. 1, and requires a relatively high programming voltage. Furthermore, the Flash technology is difficult to integrate with CMOS, and has relatively low endurance.

In many applications there is a need for a programmable memory cell capable of storing non-volatile data, and having increased access speeds and low energy consumption.

### SUMMARY OF THE INVENTION

It is an aim of embodiments of the present invention to at least partially address one or more needs in the prior art.

According to one aspect of the present invention, there is provided a memory device comprising at least one memory cell comprising: a first transistor coupled between a first storage node and a first supply voltage; a second transistor coupled between a second storage node and said first supply voltage, a control terminal of said first transistor being coupled to said second storage node, and a control terminal of said second transistor being coupled to said first storage node; a first resistance switching element coupled in series with said first transistor; and a second resistance switching element coupled in series with said second transistor; and control circuitry adapted to apply, during a programming phase of the first resistance switching element, a second supply voltage to said second storage node to active said first transistor, and then to apply said second supply voltage to said first storage node to generate a first write current through said first transistor and said first resistance switching element.

According to one embodiment, the control circuitry is further adapted to isolate said second storage node from said second supply voltage, and then to apply, during a programming phase of the second resistance switching element, said second supply voltage to said second storage node to generate a second write current through said second transistor and said second resistance switching element.

According to another embodiment, the at least one memory cell further comprises: a third transistor coupled between said first storage node and a first access line; and a fourth transistor coupled between said second storage node and a second access line; wherein said control circuitry is arranged to control said third transistor via a first control line to apply said second supply voltage to said first storage node, and to control said fourth transistor via a second control line to supply said second supply voltage to said second storage node.

According to another embodiment, the first resistance switching element is coupled in series with said third transistor between said first storage node and said first access line, and the second resistance switching element is coupled in series with said fourth transistor between said second storage node and said second access line.

According to another embodiment, the first resistance switching element is coupled between said first storage node and said third transistor, and the second resistance switching element is coupled between said second storage node and said fourth transistor.

According to another embodiment, the first resistance switching element is coupled between said third transistor and said first access line, and the second resistance switching element is coupled between said fourth transistor and said second access line.

According to another embodiment, the third and fourth transistors are adapted to have a lower threshold voltage than said first and second transistors.

According to another embodiment, the at least one memory cell further comprises a fifth transistor coupled between said first and second storage nodes.

According to another embodiment, the first and second resistance switching elements are respectively coupled between said first and second transistors and said first supply voltage.

According to another embodiment, the first and second resistance switching elements are respectively coupled between said first and second storage nodes and said first and second transistors.

According to another embodiment, the memory device further comprises programming circuitry adapted to program the resistances of said first and second resistance switching elements based on input data.

According to another embodiment, the first transistor is the only transistor of a first inverter of said at least one memory cell, and the second transistor is the only transistor of a second inverter of said at least one memory cell.

According to another embodiment, the first and second resistance switching elements are each one of: thermally assisted switching elements; oxide resistive elements; conductive bridging elements; phase change elements; programmable metallization elements; spin transfer torque elements; and field-induced magnetic switching (FIMS) elements.

According to a further aspect of the present invention, there is provided a random access memory comprising an array of the above memory devices.

According to a further aspect of the present invention, there is provided a data latch comprising the above memory device.

According to a further aspect of the present invention, there is provided a method of programming resistance switching elements of at least one memory cell comprising at least one memory cell comprising a first transistor coupled between a first storage node and a first supply voltage, a second transistor coupled between a second storage node and said first supply voltage, a control terminal of said first transistor being coupled to said second storage node, and a control terminal of said second transistor being coupled to said first storage node, a first resistance switching element coupled in series with said first transistor, a second resistance switching element coupled in series with said second transistor, the method comprising, during a programming phase of the first resistance switching element, the consecutive steps of: applying a second supply voltage to said second storage node to active said first transistor; and applying said second supply voltage to said first storage node to generate a first write current through said first transistor and said first resistance switching element.

According to one embodiment, the method further comprises, during a programming phase of the second resistance switching element after said step of applying said second supply voltage to said first storage node, the consecutive steps of: isolating said second storage node from said second supply voltage; and applying again said second supply voltage to said second storage node to generate a second write current through said second transistor and said second resistance switching element.

According to another embodiment, the at least one memory cell further comprises a third transistor coupled between said first storage node and a first access line and a fourth transistor coupled between said second storage node and a second access line, wherein said step of applying said second supply voltage to said first storage node comprises activating said third transistor, and said step of applying said second supply voltage to said second storage node comprises activating said fourth transistor.

According to another embodiment, the at least one memory cell further comprises a fifth transistor coupled between said first and second storage nodes, the method further comprising activating said fifth transistor between the programming phases of the first and second resistance switching elements.

### BRIEF DESCRIPTION OF THE DRAWINGS

The foregoing and other purposes, features, aspects and advantages of the invention will become apparent from the following detailed description of embodiments, given by way of illustration and not limitation with reference to the accompanying drawings, in which:

FIG. 1 (described above) illustrates a volatile SRAM cell;

FIG. 2 illustrates a memory cell with non-volatile data storage according to an embodiment of the present invention;

FIG. 3 illustrates programming circuitry for programming the non-volatile portion of the memory cell of FIG. 2;

FIGS. 4A and 4B are timing diagrams showing examples of signals for programming the non-volatile portion of the memory cell;

FIGS. 5A and 5B schematically represent examples of the programming of a specific resistance switching memory device;

FIG. 6 illustrates an example of control circuitry for copying data stored by non-volatile data storage elements to volatile data storage elements of the memory cell;

FIGS. 7A and 7B are timing diagrams showing examples of signals in the circuitry of FIG. 6;

FIGS. 8A to 8D each illustrate a memory cell with non-volatile data storage according to further embodiments of the present invention;

FIG. 9 illustrates a memory array according to an embodiment of the present invention; and

FIG. 10 illustrates a flip-flop comprising a non-volatile memory cell latch according to an embodiment of the present invention.

Throughout the figures, like features have been labelled with like reference numerals.

### DETAILED DESCRIPTION OF EMBODIMENTS OF THE PRESENT INVENTION

Only those features useful for an understanding of the invention have been illustrated in the figures and will be described in detail in the following. Other aspects, such as the particular applications of the memory cell, have not been described in detail, the memory cell being suitable for use in a wide range of applications.

FIG. 2 illustrates a memory cell 200 that stores, in addition to one bit of volatile data, one bit of non-volatile data. The volatile data is stored in electronic form by a latch.

The non-volatile data however is stored by the physical state of a pair of resistance switching elements, as will now be described.

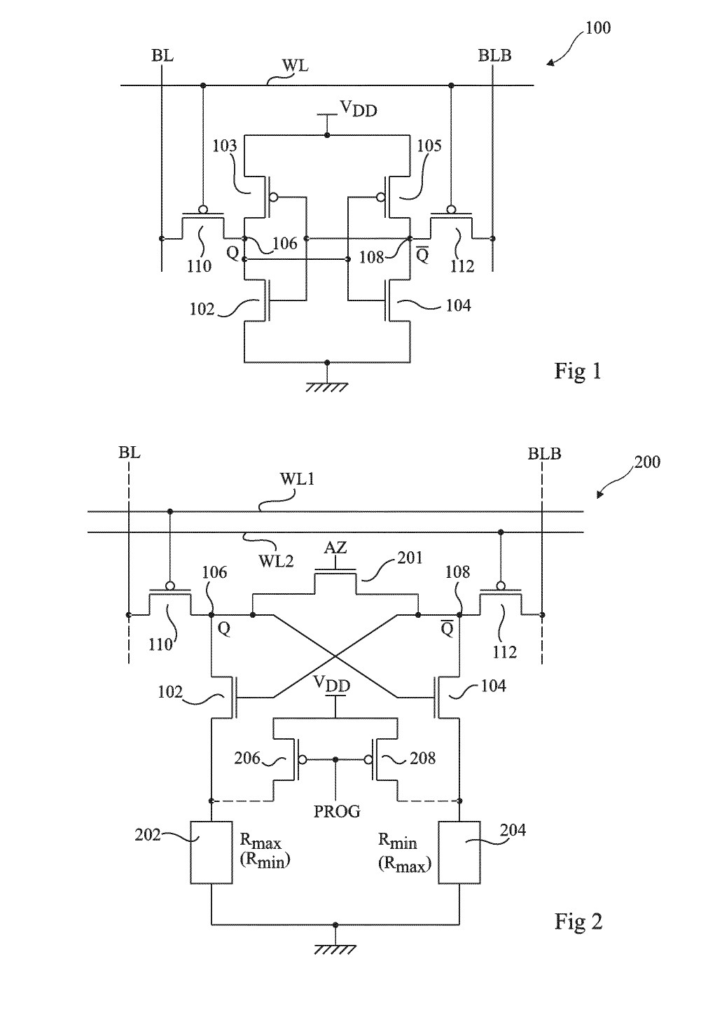

The memory cell 200 is similar to the SRAM cell 100 of FIG. 1 described above, and the common portions will not be described again in detail. However, rather than comprising six transistors, the memory cell 200 comprises five transistors. Indeed, the PMOS transistors 103 and 105 forming half of each inverter are removed, and thus there is no connection of the storage nodes 106 or 108 to the supply voltage V_{DD} in memory cell 200. An optional NMOS transistor 201 is coupled between the storage nodes 106 and 108, and is controlled at its gate node by a control signal AZ. Also, rather than being controlled by a single write line WL, the transistors 110, 112 are controlled independently by separate write lines WL1 and WL2 respectively.

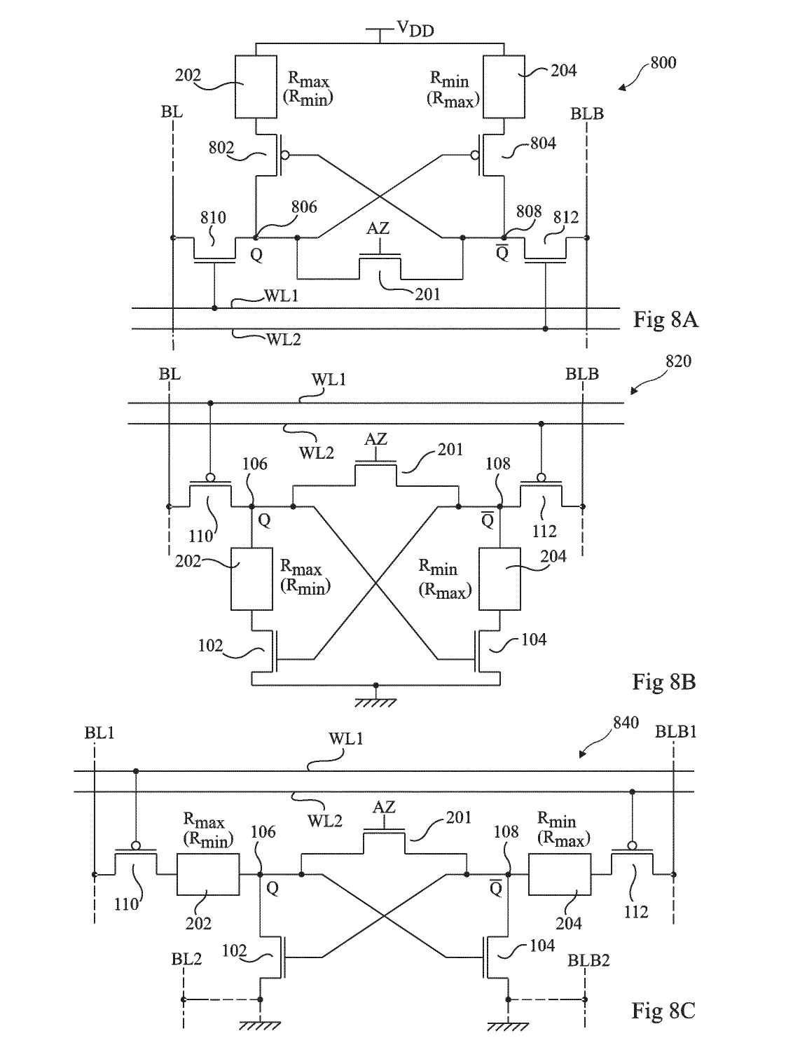

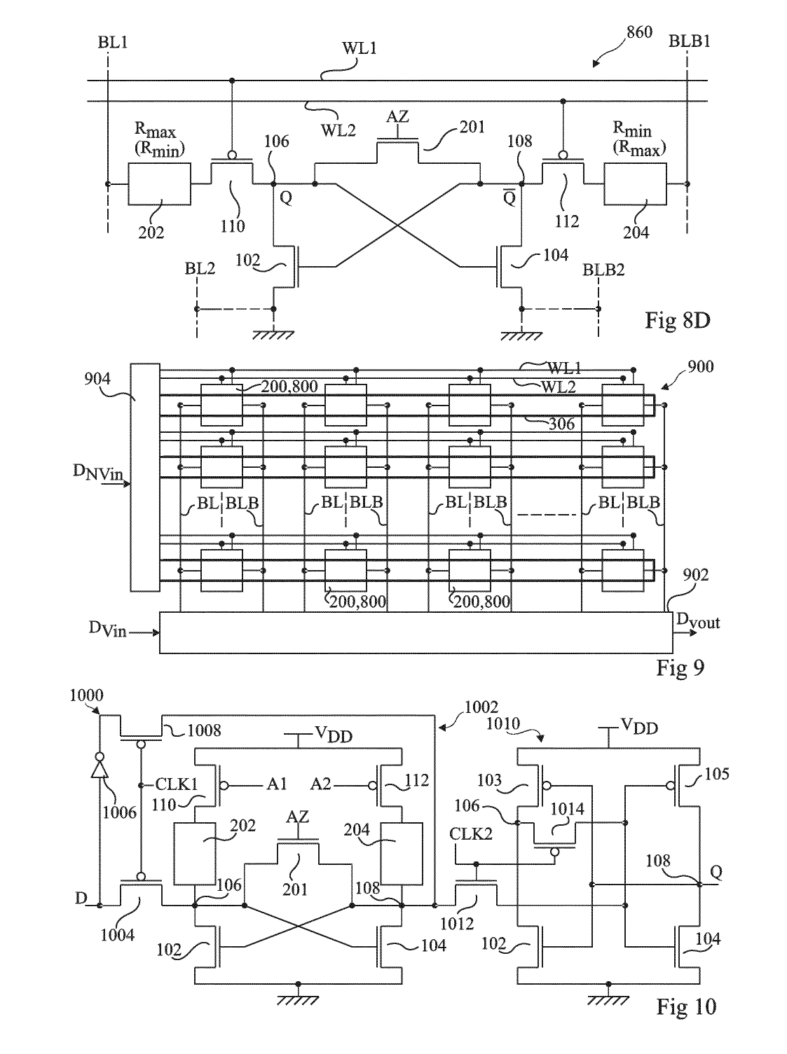

Furthermore, the memory cell 200 additionally comprises resistance switching elements 202 and 204, which are coupled between the respective sources of transistors 102 and 104 and the ground voltage. Alternatively, element 202 could be coupled between the storage node 106 and the drain of transistor 102, while element 204 could be coupled between the storage node 108 and the drain of transistor 104. This embodiment is described in more detail below with reference to FIG. 8B. As yet a further alternative, element 202 could be coupled between node 106 and transistor 110, and element 204 could be coupled between node 108 and transistor 112. Such an embodiment is described in more detail below with reference to FIG. 8C. As yet a further alternative, element 202 could be coupled between PMOS transistor 110 and the bit line BL, while element 204 could be coupled between PMOS transistor 112 and bit line BLB. Such an embodiment is described in more detail below with reference to FIG. 8D.

The resistance switching elements 202 and 204 are any resistive elements switchable between two resistance values. Such elements maintain the programmed resistive state even after a supply voltage is removed. The resistance switching elements 202, 204 are programmed to have opposite values, and the relative resistance values of the elements indicate one binary data value.

For example, the resistance switching elements 202, 204 are based on magnetic tunneling junctions (MTJs), such as field-induced magnetic switching (FIMS) elements, thermally assisted switching (TAS) elements or STT (spin transfer torque) elements. TAS-MRAM are for example discussed in more detail in the publication titled “Thermally Assisted MRAM”, Prejbeanu et al., and FIMS-MRAM (magnetic random access memory) are for example discussed in more detail in the publication titled “Magnetoresistive random access memory using magnetic tunnel junctions”, S. Tehrani, Proceedings of IEEE, 91(5):3707-714, May 2003

Alternatively, the resistance switching elements 202, 204 could be other types of resistance switching memory devices, including those used in programmable metallization cells, such as phase change RAM (PCRAM).

Whatever the type of resistance switching element, information is stored by setting one of the elements 202, 204 at a relatively high resistance (Rₘₐₓ), and the other at a relatively low resistance (Rₘᵢₙ). Each of the resistance switching elements 202, 204 for example has just two resistive states corresponding to the high and low resistances Rₘₐₓ and Rₘᵢₙ, although the exact values of Rₘᵢₙ and Rₘₐₓ may vary depending on conditions such as temperature, process variations etc. The non-volatile data value represented by the resistive elements 202, 204 depends on which of the resistive elements is at the resistance Rₘₐₓ and Rₘᵢₙ, in other words on the relative resistances. The resistance elements 202, 204 are for example selected such that Rₘₐₓ is always significantly greater than Rₘᵢₙ, for example at least 20 percent greater. In general, the ratio between the resistance Rₘₐₓ and the resistance Rₘᵢₙ is for example between 1.2 and 10000, depending on the type of elements used. In one example, Rₘᵢₙ is in the region of 2.5 k ohms, and Rₘₐₓ is in the region of 5 k ohms, although many other values are possible.

In the SRAM cell 100 of FIG. 1, transistors 103 and 105 are coupled to the supply rail V_{DD} and perform the role of maintaining the high state of Q or Q̅ at node 106 or 108 when the cell is in standby between write and read operations. In the cell 200 of FIG. 2, in which these transistors have been removed, the high state of Q or Q̅ is maintained by leakage current passing through the PMOS transistor 110 or 112, from the corresponding bit line BL or BLB. For example, the bit lines BL and BLB are charged to the supply voltage V_{DD} at least periodically during the standby state, to generate the leakage current.

The threshold voltages of the PMOS transistors 110, 112 are lower than those of NMOS transistors 102, 104, such that the leakage current when in the off state for a given drain-source voltage VDS is greater in transistors 110 and 112 than in transistor 102 or 104. In other words, since the same amount of current flows through the transistors 102 and 110 or 104 and 112 which are coupled in series, the voltage drop across transistors 110 and 112 is lower than across transistors 102 and 104 thereby keeping the corresponding node 106 or 108 at a voltage high enough to be seen as a high logic level. The particular threshold voltages will depend on the technology used. But as an example, the threshold voltages of PMOS transistors 110, 112 are chosen to be in the range 0.3 to 0.5 V, while the threshold voltages of NMOS transistors 102, 104 are in the range 0.4 to 0.6 V. In any case, the ratio I_{Offp}/I_{Offn} is selected for example to be greater than 25, and preferably greater than 100.

In operation, for reading and writing data to the volatile portion of the memory cell 200, in other words to the storage nodes 106 and 108, the process is the same as for the memory cell 100, and is not affected by the programmed resistance values of the resistance switching elements 202 and 204. Briefly, writing a bit of data to nodes 106, 108 involves applying, while transistors 110 and 112 are turned on by a low voltage to both write lines WL1, WL2, a high or low voltage to bit line BL depending on the data to be stored, and the opposite voltage to bit line BLB. Reading the data from nodes 106 and 108 involves pre-charging the bit lines BL and BLB, and then turning on transistors 110 and 112 and determining which bit line voltage drops first, with the aid of a sense amplifier (not illustrated), which amplifies the voltage difference between the bit lines. During such read and write operations the signal AZ controlling transistor AZ is for example never asserted. Preferably, so as not to slow the read and write operations to the volatile storage nodes and to prevent a bit-flip during a read operation, the value of Rₘₐₓ is chosen not to be greater than around 5 k ohms, although this value will depend on the particular technology used, and in particular on the resistance of the transistors.

Independently of this normal SRAM operation, the resistance switching elements may be programmed to store non-volatile data, and the memory cell may be controlled to transfer this data, from physical storage determined by the resistive states of elements 202, 204, to electronic storage determined by the voltage states of the storage nodes 106, 108. Once transferred, this data may be read from the SRAM cell in a standard fashion.

In order to program the resistive states of the elements 202 and 204, a current is passed through each element. In the case of TAS-MRAM, such a current is used to heat the elements, aiding the programming of the resistive states by a magnetic field generated independently. For other types of resistance switching elements, such as spin transfer torque (STT) elements, the level or polarity of this current may be used to directly program the resistive elements.

The supply of this current in the memory cell 200 could be provided by illustrated PMOS transistors 206 and 208 coupled between the respective elements 202, 204 and the supply voltage V_{DD}. Transistors 206, 208 are controlled by a control signal PROG, which activates these transistors shortly before each element 202, 204 is to be programmed. However, disadvantages of this solution are that it is relatively power consuming and adds an additional two transistors in each memory cell.

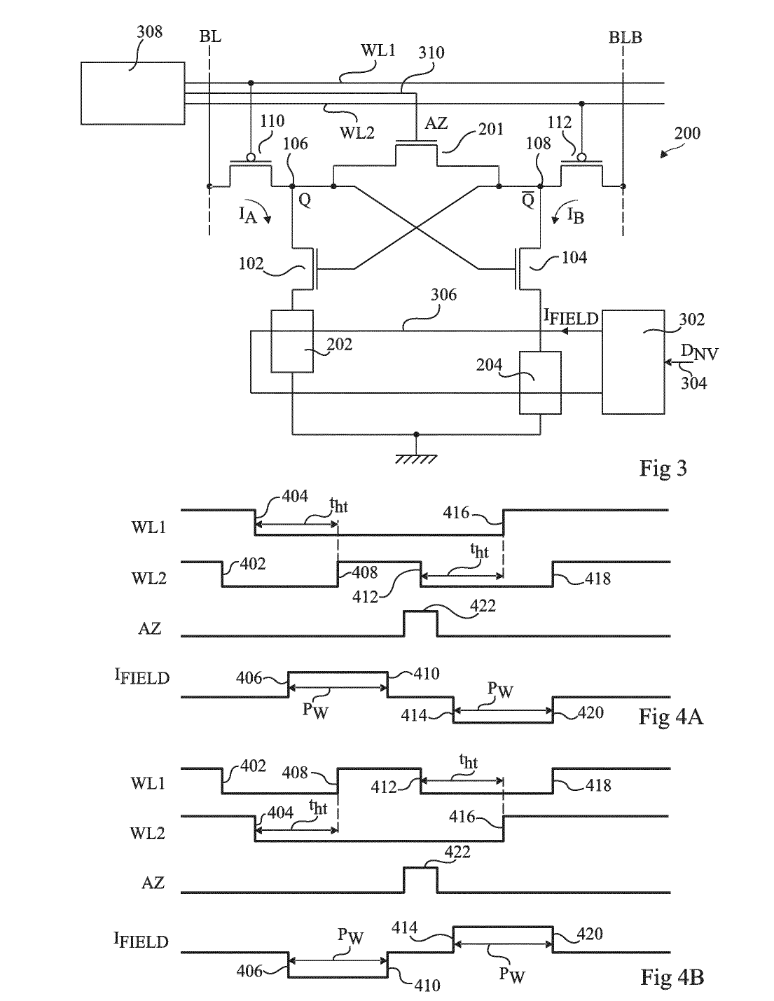

An alternative approach will now be described with reference to FIG. 3, for the specific case that the resistance switching elements 202, 204 are TAS elements.

FIG. 3 illustrates the memory cell 200, along with a field generation circuitry 302 arranged to program the resistance switching elements 202 and 204 based on one bit of non-volatile data D_{NV} received on an input line 304. In particular, based on the non-volatile data D_{NV}, the circuitry 302 generates a current I_{FIELD}, which is provided on a conductive track 306 that passes by the resistance switching elements 202 and 204. The current I_{FIELD} flowing through the conductive track 306 generates a magnetic field, which passes through the resistance switching elements, and programs their resistive state.

Prior to supplying the current I_{FIELD} to program each of the resistance switching elements 202, 204, the resistance switching elements are heated by passing a current through them. For this, write control circuitry 308 is provided, which independently controls the PMOS transistors 110, 112, and optionally also the NMOS transistor 201. In particular, circuitry 308 is coupled to the write lines WL1 and WL2, and optionally to the gate terminal of transistor 201 via a line 310. The operation of the field generation circuitry 302 and write control circuitry 308 will now be described in more detail with reference to the timing diagrams of FIGS. 4A and 4B.

FIG. 4A illustrates timing diagrams showing examples of the signals WL1, WL2, AZ and I_{FIELD} of the circuit of FIG. 3, during a programming phase of the resistance switching elements 202 and 204, in the case that the elements 202, 204 are TAS elements.

Initially, the signals WL1 and WL2 are high, such that the storage nodes 106, 108 are isolated from the bit lines BL and BLB. Then, while the supply voltage V_{DD} is applied to the bit lines BL and BLB, a falling edge 402 of signal WL2 activates PMOS transistor 112, thereby coupling storage node 108 to the supply voltage V_{DD}. This voltage thereby activates the NMOS transistor 102, and brings down the voltage at node 106 if it is not already low. A falling edge 404 of signal WL1 then activates transistor 110, such that a current I_{A} flows from the bit line BL through transistors 110 and 102 and element 202 to ground. This current I_{A} heats element 202. The current I_{FIELD} is applied for a write period P_{W}, as shown by rising edge 406, to program element 202. Period P_{w} for example has a duration of about 20 ns. The polarity of the current I_{FIELD} determines the logic value of the non-volatile data that will be stored by the resistance switching elements 202, 204. In the example of FIG. 4A, a positive current is applied for programming element 202, which for example results in a high resistance of element 202.

The current I_{A} triggered by edge 404 continues for a time tₕₜ, until a rising edge 408 of signal WL2, which isolates again the storage node 108 from bit line BLB, and leads to a drop in the voltage Q̅ at node 108. After a cool down period, a falling edge 410 of the signal I_{FIELD} then ends the write period P_{W} of element 202.

In preparation for programming element 204, a falling edge 412 of signal WL2 then activates PMOS transistor 112, and a current I_{B} starts to flow through transistor 104 and element 204. Then, the current I_{FIELD} is applied for a write period P_{W}, as shown by falling edge 414 of this signal, to program element 204. Thus element 204 is programmed with the opposite resistive state to element 202. The current I_{B} triggered by falling edge 412 continues for a time tₕₜ, until a rising edge 416 of signal WL1, which deactivates transistor 110, thereby stopping the current I_{A} through element 202, and then a rising edge 418 of signal WL2 deactivates transistor 112. After a cool down period, a rising edge of the signal I_{FIELD} then ends the write period P_{W} of element 204.

Thus the time for programming each element 202, 204 is for example in the region of 35 ns, and thus given that the programming of each element is performed consecutively in two cycles, the programming for example takes in the region of 70 ns. However, the heating and cooling-off times will vary based on factors such as the materials used, their volumes, etc., and also the heat currents that are applied, and thus the above values are given only as approximate examples.

The signal AZ is optionally asserted to aid the initialisation of the current I_{B}. Thus, the signal AZ is asserted for a short pulse 422 starting shortly before the falling edge 412 of signal WL2 and for example ending before the falling edge 414 of signal I_{FIELD}. This has the effect of saturating the transistor 104, thereby aiding the initialisation of the current I_{B}.

FIG. 4B illustrates timing diagrams showing examples of the signals WL1, WL2, AZ and I_{FIELD} of the circuit of FIG. 3, during a programming phase of the resistance switching elements 202 and 204 similar to that of FIG. 4A, except that the element 204 is programmed first, followed by element 202. Thus the signals WL1 and WL2 are interchanged. Furthermore, the elements 202 and 204 are programmed with a same logic value to the example of FIG. 4A, and thus the signal I_{FIELD} goes to a negative current at edge 406 and to a positive current at edge 414.

In the case that elements 202, 204 are PCRAM elements, the selection of their resistive states is performed by controlling the heating rates of the elements. For example, the circuit 308 is adapted to control the voltage level applied to the bit lines BL and BLB such that the heating current is appropriate for programming the required resistive state of the element. In such a case, the circuitry 302 and conductive track 306 are omitted.

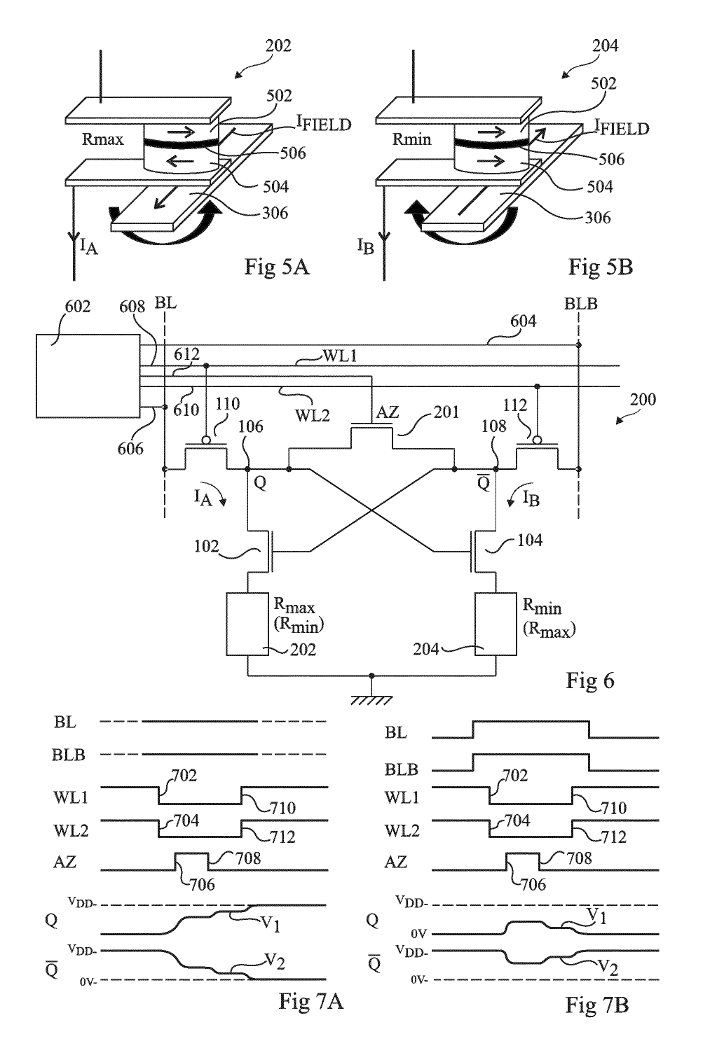

FIGS. 5A and 5B show the resistance switching elements 202, 204 in more detail in the example that they are TAS elements. Each of the resistance switching elements 202, 204 comprises a pinned ferromagnetic plate 502 and a free ferromagnetic plate 504, plates 502 and 504 sandwiching a tunnel oxide layer 506. The conductive track 306 passes close to the free plate 504 of ferromagnetic material, such that it is affected by the magnetic field generated by the current I_{FIELD} flowing through track 306. The pinned plate 502 for example has a magnetic orientation in a first direction, while the magnetic orientation of plate 504 may be programmed, by the polarity of the current I_{FIELD}, to be in the same or opposite direction to that of plate 502.

FIG. 5A illustrates the case in which the magnetic orientations are in opposite directions in the plates 502, 504, resulting in a maximum resistance Rₘₐₓ of the resistance switching element 202, for example in the range 2 k to 5 k Ohms.

FIG. 5B illustrates the case in which the magnetic orientations are in a same direction in the plates 502 and 504, resulting in a minimum resistance Rₘᵢₙ of the resistance switching element 204, for example in the range of 100 to 3 k Ohms.

FIG. 6 illustrates the memory cell 200 along with transfer control circuitry 602, for controlling the transfer of data stored in the non-volatile portion of the memory cell to the volatile data storage portion. In particular, the circuitry 602 comprises output lines 604 and 606 coupled to bit lines BL and BLB respectively, output lines 608, 610 coupled to the word lines WL1, WL2 respectively, and an output line 612 coupled to the control terminal of transistor 201 to provide the signal AZ.

Examples of the signals on the bit lines BL, BLB, word lines WL1, WL2, the signal AZ, and the resulting voltages Q and Q̅ at storage nodes 106, 108 during a non-volatile element reading phase will now be described with reference to FIGS. 7A and 7B.

In general, the non-volatile element reading phase comprises applying by the control circuitry 602 a supply voltage to each of the storage nodes 106, 108, via the bit lines BL and BLB. This generates a current through each of the resistance switching elements 202, 204, such that the voltages at nodes 106, 108 will depend on the relative resistances of the elements 202, 204.

FIG. 7A assumes that the resistance switching elements are programmed such that element 202 has the resistance Rₘₐₓ, and element 204 has the resistance Rₘᵢₙ, and that the SRAM cell is initially in a state in which Q is low and Q̅ is high.

Initially, the circuitry 602 applies a high voltage to each of the bit lines BL, BLB, for example at the supply voltage V_{DD}. The bit lines BL and BLB are likely to be close to or at the supply voltage V_{DD} during a standby or read phase prior to the transfer phase, but during such phases they are generally only periodically charged to the supply voltage, and for this reason the voltages of BL and BLB prior to and after the transfer phase have been indicated by dashed lines in FIG. 7A. On the contrary, during the non-volatile element reading phase, the supply voltage is constantly applied to the bit lines BL, BLB, as indicated by solid lines in FIG. 7A, such that currents may be drawn from the bit lines.

Then, the word line voltages WL1 and WL2 are brought low at falling edges 702 and 704 respectively, to activate the transistors 110 and 112. Thus transistor 104 will initially be non-conducting, and transistor 102 conducting. However, due to the resistance Rₘₐₓ of element 202, the current flowing through transistor 102 will be limited. This current causes the voltage Q to start to rise.

Optionally, the signal AZ is then asserted, as shown by a rising edge 706, which has the effect of bridging nodes 106 and 108 via the NMOS transistor 201, thereby bringing the voltages Q and Q̅ more quickly to an intermediate level between V_{DD} and ground. This can be particularly beneficial in the case of relatively low resistances of Rₘᵢₙ and Rₘₐₓ.

After the signal AZ is brought low by a falling edge 708, the voltages Q and Q̅ settle at levels V₁ and V₂ respectively, which are significantly different due to the difference between the resistances Rₘₐₓ and Rₘᵢₙ. The PMOS transistors 110, 112 are chosen to have equal dimensions and thus very similar off resistances, such that the voltage drop across each transistor 110, 112 will be proportional to the current level flowing through it. Thus, the lower voltage drop across transistor 110 will cause a higher voltage Q at node 106. Thus due to the difference in the resistances of resistive elements 202 and 204, the equilibrium position will be that the level V₁ of voltage Q at node 106 is closer to V_{DD}, and the level V₂ of voltage Q̅ at node 108 will be closer to 0 V.

Then, the word line signals WL1 and WL2 go high at edges 710 and 712 respectively, isolating the storage elements 106, 108 from bit lines BL and BLB, and the states of Q and Q̅ will settle to the closest stable state. In particular, due to the voltage difference, even if small, between the voltages Q and Q̅, the storage nodes 106, 108 will settle to a state in which Q is high and Q̅ is low, which corresponds to the state stored by the elements 202 and 204.

FIG. 7B illustrates the case in which Q and Q̅ are again initially equal to 0 V and V_{DD} respectively, but in which element 202 is at Rₘᵢₙ, and element 204 at Rₘₐₓ. In this case, transistor 102 will initially still be conducting, and transistor 104 non-conducting, but again the voltage at node 106 will rise due to the current flowing through the resistance switching element 202. However, after the optional assertion of the signal AZ, the current through element 204 will be a low current due to the high resistance of element 204, and thus the voltage level V₁ of will stay relatively low, and the voltage level V₂ of Q̅ will stay relatively high. Then, when the word line signals WL1 and WL2 are brought high again, isolating the storage nodes 106, 108 from the respective bit lines BL and BLB, the states of storage nodes 106, 108 will settle back to their original states, in which Q is low and Q̅ is high.

In both FIGS. 7A and 7B, the duration that the word lines WL1 and WL2 are activated is for example in the region of 1 ns, and thus such a data transfer from the non-volatile storage to the volatile storage can be performed in approximately only 1 ns, a time comparable to the read and write times of the SRAM portion of the memory cell 200.

FIG. 8A illustrates a memory cell 800, which is similar to cell 200 of FIG. 2, but in which the NMOS transistors 102, 104 are replaced by PMOS transistors 802 and 804 coupled between respective nodes 806, 808 and a supply voltage V_{DD}, and the PMOS transistors 110, 112 are replaced by NMOS transistors 810, 812 coupled between the respective bit lines BL and BLB and the respective nodes 806, 808. The resistance switching elements 202, 204 are coupled between the sources of transistors 802, 804 respectively and the supply voltage V_{DD}, although they could alternatively respectively be coupled between transistors 802, 804 and storage nodes 806, 808. In this circuit, the threshold voltages of transistors 810 and 812 are lower than those of transistors 802 and 804, such that a leakage current will ensure the low state of node 806 or 808 during the standby phase between write operations. Furthermore, the bit lines BL and BLB are for example at least periodically brought to a low voltage during the standby phase.

The circuit 800 operates in a similar fashion to the circuit 200, except that transistors 810, 812 are activated by a high voltage level on the word lines WL1, WL2, and a low supply voltage, for example at 0 V, will be applied by circuitry 602 of FIG. 6 to the bit lines BL, BLB during the transfer phase from the non-volatile storage elements 202, 204 to the volatile storage nodes 806, 808.

FIG. 8B illustrates a memory cell 820, which is similar to cell 200 of FIG. 2, but in which, rather than being coupled between transistors 102, 104 respectively and ground, the resistance switching elements 202, 204 are coupled respectively between node 106 and transistor 102, and between node 108 and transistor 104.

Operation of the memory cell 820 is very similar to that of the memory cell 200 of FIG. 2, and will not be described again in detail.

FIG. 8C illustrates a memory cell 840, which is similar to cell 200 of FIG. 2, but in which, rather than being coupled between transistors 102, 104 respectively and ground, the resistance switching elements 202, 204 are coupled respectively between node 106 and transistor 110, and between node 108 and transistor 112.

As illustrated in FIG. 8C, the sources of transistors 102, 104 may be connected directly to ground, or alternatively they are coupled respectively to further complementary bit lines BL2 and BLB2, bit lines BL and BLB being relabelled BL1 and BLB1 respectively.

In the case that the sources of transistors 102, 104 are connected to ground, operation of the memory cell 840 is similar to that of memory cell 200, except that, when the non-volatile data is transferred to the storage nodes 106, 108, a programmed resistance of element 202 of Rₘₐₓ will result in a low voltage at node 106, and a programmed resistance of element 202 of Rₘᵢₙ will result in a high voltage at node 106. Similarly, resistances of Rₘₐₓ and Rₘᵢₙ will result in low and high voltages respectively at node 108 during the non-volatile to volatile data transfer. Advantageously, it has been found that such a positioning of the elements 202, 204 leads to particularly good performance of the memory cell. In particular, it enables relatively small transistors to be used in order to drive the programming current, for example for heating the elements 202, 204.

In the case that the sources of transistors 102, 104 are coupled to the bit lines BL2, BLB2 respectively, this permits current to be passed through the elements 202, 204 in either direction during a programming phase of the elements 202, 204. In particular, there is no longer any connection to the supply voltages V_{DD} or ground in the memory cell, and instead voltages applied to bit lines BL1, BL2 determine the current flowing through element 202, while voltages applied to bit lines BLB1, BLB2 determine the current flowing through element 204. Elements 202, 204 are for example STT (spin transfer torque) devices, which are programmed by the polarity of the current that is passed through them.

In operation, the bit lines BL2 and BLB2 are for example coupled to ground during the reading phase of volatile data stored at nodes 106, 108, and likewise during the transfer phase of the data programmed by the resistance switching elements to the storage nodes 106, 108. During a programming phase of the elements 202, 204, the control block 308 of FIG. 3 is adapted to apply the sequence of signal described above in relation to FIGS. 4A and 4B. However, rather than the signal I_{FIELD}, the circuitry 302 is for example adapted to generate a voltage between bit lines BL1 and BLB1, and between bit lines BL2 and BLB2, the direction of the applied voltage determining the direction of the current flow and thus the programmed resistive state of the elements 202, 204. Thus, in such an embodiment, the field generation circuitry 302 is for example omitted.

For example, the elements 202, 204 are each programmed to have resistance Rₘₐₓ if a current is applied from the storage node 106/108 towards the bit line BL1/BLB1 respectively, and resistance Rₘᵢₙ if a current is applied in the opposite direction. Thus, to program element 202 at resistance Rₘₐₓ and element 204 at resistance Rₘᵢₙ, the supply voltage V_{DD} is for example applied to bit lines BL2 and BLB1, and a ground voltage is for example applied to bit lines BL1 and BLB2. Alternatively, to program element 202 at resistance Rₘᵢₙ and element 204 at resistance Rₘₐₓ, the supply voltage V_{DD} is for example applied to bit lines BL1 and BLB2, and a ground voltage is for example applied to bit lines BLB1 and BL2.

FIG. 8D illustrates a memory cell 860, which is similar to cell 840 of FIG. 8C, but in which, rather than being coupled respectively between node 106 and transistor 110, and node 108 and transistor 112, the resistance switching elements 202, 204 are coupled respectively between transistor 110 and bit line BL1, and between transistor 112 and bit line BLB1.

Operation of the memory cell 860 is the same as that of memory cell 840 in both the case that the sources of transistors 102, 104 are connected to ground and the case that they are connected to the bit lines BL2, BLB2, and will not be described again in detail.

Of course, it will be apparent to those skilled in the art that any of the memory cells 820, 840 and 860 the NMOS transistors 102, 104 could be replaced by PMOS transistors, in a similar fashion to the embodiment of FIG. 8A.

FIG. 9 illustrates a memory array 900 of the memory cells 200 and/or 800, according to an example in which the resistance elements 202, 204 are programmed by a magnetic field. In this example, the memory cells 200, 800 are arranged in columns and rows, each being coupled to bit lines BL and BLB common to each of the columns. The bit lines are coupled to control circuitry 902, which for example receives volatile input data D_{VIN}, and volatile output data D_{VOUT}, which could be the externally inputted volatile data, or volatile data that is generated from a transfer of the non-volatile data stored by the resistance switching elements. The circuitry 902 for example also controls the voltages on the bit lines BL and BLB during the transfer phase, and if appropriate during the writing of non-volatile data.

Each of the cells 200, 800 is also coupled to the corresponding word lines WL1, WL2 common to each row of cells, and a conductive track 306 forms a loop passing by each cell and conducting the current I_{FIELD} for writing to the resistance switching elements of each of the memory cells. Each of the lines WL1, WL2 and 306 is controlled by control circuitry 904, which for example comprises the circuitry 302 and 602 for each row, and receives input non-volatile data D_{NVin}, and provides the current I_{FIELD} of the corresponding polarity. While not shown in FIG. 9, an additional line is for example present for each row of memory cell to provide the control signal AZ, in the case that the memory cells comprise the optional transistor 201 of FIG. 2, 6 or 8.

The writing of the non-volatile data is for example performed row by row, in two phases. During a first phase, only the resistance switching elements 202, 204 of cells for which a first logic value, such as logic “0”, is to be programmed are heated. Such selective heating is for example performed by only applying, during the method of FIG. 4A/4B, the supply voltage to the bit lines of cells that are to be heated. Then, when the corresponding current is applied to the conductive track 306, the resistive states of only the elements that have been heated will be programmed. During the second phase, the resistance switching elements 202, 204 of the other cells, for which the second logic value, for example a logic “1”, is to be programmed are heated. Then, when the corresponding write current is applied to the conductive track 306, again only the resistive states of the elements that have been heated will be programmed.

As indicated by dashed lines in FIG. 9, the memory array 900 may comprise any number of rows of cells and any number of columns of cells, depending on the desired storage capacity.

Of course, the memory cells 200, 800 of FIG. 9 could alternatively be implemented by one of the memory cells 820, 840 or 860 of FIGS. 8B to 8D. Furthermore, it will be apparent to those skilled in the art how the array of FIG. 9 could be adapted in the case that the resistance switching elements 202, 204 of each memory cell are not programmed by a magnetic field, but by an alternative technique such as a current intensity or polarity applied to these elements. In such a case, the conductive tracks 306 are for example omitted.

FIG. 10 illustrates a flip-flop 1000 comprising a memory cell 1002, which is similar to the memory cell 200 of FIG. 2, except that the resistive elements 202, 204 are positioned between the storage nodes 106, 108 and the transistors 110, 112 respectively. Alternatively, the elements 202, 204 could be coupled between the PMOS transistors 110, 112 respectively and the supply voltage V_{DD}, or between the NMOS transistors 102, 104 respectively and the ground voltage. However, their position between the PMOS transistors 110, 112 and storage nodes 106, 108 respectively advantageously allows the dimensions of the transistors to be relatively small. Furthermore, the transistors 110, 112 are not coupled to bit lines, but directly to the supply voltage V_{DD}. Furthermore, transistor 110 is controlled by a signal A1, rather than WL1, and transistor 112 is controlled by a signal A2, rather than WL2, but the form of these signals during programming phases of the resistive elements is the same as for the signals WL1, WL2.

The storage node 106 of memory cell 1002 receives data D via a PMOS transistor 1004, while this data is also provided to storage node 108 via an inverter 1006 and PMOS transistor 1008 coupled in series. PMOS transistors 1004, 1008 are controlled by a clock signal CLK1. Alternatively, PMOS transistors 1004, 1008 could be replaced by NMOS transistors. Storage node 108 is further coupled to a further SRAM cell or latch 1010, similar to cell 100 of FIG. 1, except that it is accessed via an NMOS transistor 1012 coupled between node 108 of cell 1002 and the gates of transistors 104, 105 of cell 1010. Again, NMOS transistor 1012 could be replaced by a PMOS transistor. Furthermore, rather than a permanent connection, node 106 is coupled to the gates of transistors 104 and 105 via a PMOS transistor 1014. This transistor allows the feedback path between the two inverters to be broken while the flip-flop 1000 is being written to. Both transistors 1012 and 1014 are controlled by a clock signal CLK2, which is for example the same as clock signal CLK1, except during writing/reading to/from the resistance switching elements 202, 204. In particular, the clocks CLK1 and CLK2 are for example generated by a generation block (not illustrated) based on a common clock signal CLK, and on a control signal MAG indicating when a read or write of the elements 202, 204 is to be performed, in which case CLK1 is for example kept high and CLK2 is for example kept low.

In operation, data D clocked into the memory cell 1002 on a falling edge of clock CLK1 is then stored by the memory cell 1010 on the next rising edge of clock signal CLK2, ready for output from node 108 of cell 1010. An advantage of the flip-flop 1000 is that the elements 202, 204 of memory cell 1002 allow non-volatile data to be stored, which may be output by bringing low the control signals A1 and A2 and optionally asserting the AZ signal. Furthermore, the output state of the memory cell 1002 is stored by cell 1010, even during reading or writing of the volatile or non-volatile data of cell 1002.

An advantage of the embodiments of the memory cell described herein is that they are capable of storing not only one bit of volatile data, but additionally one bit of non-volatile data. Furthermore, the programmed non-volatile data can be quickly loaded to the volatile portion of the memory cell in a simple fashion, by application of a voltage to the access lines of the memory cell. This advantageously means that a state programmed in a non-volatile fashion may be quickly loaded (in less than 1 ns), for example upon activation of the memory on power-up or after a sleep period. In the case of an FPGA, this allows a circuit design to be quickly initialised, without the need of loading external data into the device to program memory latches and switches.

An advantage of the control circuitry 308 of FIG. 3, which is for example common to a plurality of memory cells, is that programming the resistance switching elements 202, 204 is performed without integrating additional transistors in each memory cell. Furthermore, because the transistor 102, 104, 802 or 804 of the memory cell 200, 800, 820, 840 or 860 is activated while a heating or programming current is passed through the corresponding element, a normal supply voltage level can be used to generate sufficient current for such a heating or programming of the element.

According to embodiments described herein, the inverters forming the memory cell are each implemented by a single transistor coupled to the same supply voltage. Thus the memory cell is connected to only one power rail: ground in FIGS. 2 and 8B to 8D; and V_{DD} in FIG. 8A. The volatile data stored by the memory is maintained by current leakage passing through the access transistors of the memory cell, and this leads to very little static current consumption during a standby state in which the volatile data is to be maintained. Furthermore, this volatile data can be independent of the programmed state of the resistive switching elements.

Furthermore, in the case that the volatile data in the memory is to be discarded during the standby state and only the non-volatile data is to be maintained, the power to the bit lines can be removed altogether, such that even the leakage current becomes negligible. The power consumption of the memory is thus extremely low during such a standby state.

Furthermore, advantageously the cell is capable of fast (in around 1 ns) write and read operations for the volatile storage portions, which may occur in a normal fashion irrespective of the programmed states of the non-volatile resistive elements. Furthermore, the write time for the non-volatile portion is also relatively fast (in around 35 ns for each memory element).

A further advantage of the memory cells described herein is that the circuit is compact, comprising only four or five transistors and two programmable resistors for the storage of one bit of non-volatile data and one bit of volatile data. Furthermore, the non-volatile data may be read without the need of additional transistors in each memory cell. Furthermore, in advanced silicon technologies, for example 65 nm or lower, the transistors of the memory circuit may be relatively small while still providing sufficient current to heat the element 202, 204.

Furthermore, the resistance switching elements 202, 204 of FIGS. 2 and 8 are for example formed in a metal layer above a silicon layer in which the transistors 102 and 104 are formed. The positioning of these resistance switching elements 202, 204 connected directly to the ground voltage in FIG. 2 or directly to the supply voltage V_{DD} in FIG. 8A is thus advantageous as a single via may be used from the silicon layer to one terminal of each resistance switching element, and the other terminal of each element can be connected directly to the corresponding supply rail rather than returning on another via to the silicon layer.

Having thus described at least one illustrative embodiment of the invention, various alterations, modifications and improvements will readily occur to those skilled in the art.

For example, while transistors 201 and 1012 are NMOS transistors, it will be apparent to those skilled in the art that this transistor could be implemented as a PMOS transistor. Furthermore, the transistor 201 is optional in all of the embodiments described herein.

Furthermore, it will be apparent to those skilled in the art that the control blocks 308 and 602 shown in FIGS. 3 and 6 could be combined to form a single control block that controls both the write phase for programming elements 202, 204 and the phase for reading the programmed states of elements 202, 204 to the volatile storage nodes.

Furthermore, it will be apparent to those skilled in the art that, while the invention has been described in relation to a memory array and flip-flop, the memory cell described herein could be used in other types of memory devices, such as FPGAs etc.

It will be apparent to those skilled in the art that the ground voltage described herein may be at 0 V, or more generally at any supply voltage V_{SS}, that could be different from 0 V.

Furthermore, while the various embodiments have been described in relation to MOS transistors, it will be apparent to those skilled in the art that the invention could be equally applied to other transistor technologies, such as bipolar transistors.

Furthermore, the features described in relation to the various embodiments could be combined in alternative embodiments in any combination.

1. A memory device comprising:
at least one memory cell comprising:
a first transistor coupled between a first storage node and a first supply voltage;
a second transistor coupled between a second storage node and said first supply voltage, a control terminal of said first transistor being coupled to said second storage node, and a control terminal of said second transistor being coupled to said first storage node;
a first resistance switching element coupled in series with said first transistor; and
a second resistance switching element (204) coupled in series with said second transistor; and
control circuitry adapted to apply, during a programming phase of the first resistance switching element, a second supply voltage to said second storage node to active said first transistor, and then to apply said second supply voltage to said first storage node to generate a first write current through said first transistor and said first resistance switching element.

2. The memory device of claim 1, wherein said control circuitry is further adapted to isolate said second storage node from said second supply voltage, and then to apply, during a programming phase of the second resistance switching element, said second supply voltage to said second storage node to generate a second write current through said second transistor and said second resistance switching element.

3. The memory device of claim 1, wherein said at least one memory cell further comprises:
a third transistor coupled between said first storage node and a first access line; and
a fourth transistor coupled between said second storage node and a second access line.

4. The memory device of claim 3, wherein said control circuitry is arranged to control said third transistor via a first control line to apply said second supply voltage to said first storage node, and to control said fourth transistor via a second control line to supply said second supply voltage to said second storage node.

5. The memory device of claim 3, wherein said first resistance switching element is coupled in series with said third transistor between said first storage node and said first access line, and wherein said second resistance switching element is coupled in series with said fourth transistor between said second storage node and said second access line.

6. The memory device of claim 5, wherein said first resistance switching element is coupled between said first storage node and said third transistor, and wherein said second resistance switching element is coupled between said second storage node and said fourth transistor.

7. The memory device of claim 5, wherein said first resistance switching element is coupled between said third transistor and said first access line, and wherein said second resistance switching element is coupled between said fourth transistor and said second access line.

8. The memory device of claim 3, wherein said third and fourth transistors are adapted to have a lower threshold voltage than said first and second transistors.

9. The memory device of claim 1, wherein said at least one memory cell further comprises a fifth transistor coupled between said first and second storage nodes.

10. The memory device of claim 1, wherein said first resistance switching element is coupled between said first transistor and said first supply voltage and wherein said second resistance switching element is coupled between said second transistor and said first supply voltage.

11. The memory device of claim 1, wherein said first resistance switching element is coupled between said first storage node and said first transistors, and wherein said second resistance switching element is coupled between said second storage node and said second transistor.

12. The memory device of claim 1, further comprising programming circuitry adapted to program the resistances of said first and second resistance switching elements based on input data.

13. The memory device of claim 1, wherein said first transistor is the only transistor of a first inverter of said at least one memory cell, and said second transistor is the only transistor of a second inverter of said at least one memory cell.

14. The memory device of claim 1, wherein said first and second resistance switching elements are one of:
thermally assisted switching elements;
oxide resistive elements;
conductive bridging elements;
phase change elements;
programmable metallization elements;
spin transfer torque elements; and
field-induced magnetic switching elements.

15. A random access memory comprising an array of the memory devices of claim 1.

16. A data latch comprising the memory device of claim 1.

17. A method of programming resistance switching elements of at least one memory cell comprising at least one memory cell comprising a first transistor coupled between a first storage node and a first supply voltage, a second transistor coupled between a second storage node and said first supply voltage, a control terminal of said first transistor being coupled to said second storage node, and a control terminal of said second transistor being coupled to said first storage node, a first resistance switching element coupled in series with said first transistor, a second resistance switching element coupled in series with said second transistor, the method comprising, during a programming phase of the first resistance switching element, the consecutive steps of:
applying a second supply voltage to said second storage node to active said first transistor; and
applying said second supply voltage to said first storage node to generate a first write current through said first transistor and said first resistance switching element.

18. The method of claim 17, further comprising, during a programming phase of the second resistance switching element after said step of applying said second supply voltage to said first storage node, the consecutive steps of:
isolating said second storage node from said second supply voltage; and
applying again said second supply voltage to said second storage node to generate a second write current through said second transistor and said second resistance switching element.

19. The method of claim 17, wherein said at least one memory cell further comprises a third transistor coupled between said first storage node and a first access line and a fourth transistor coupled between said second storage node and a second access line, wherein said step of applying said second supply voltage to said first storage node comprises activating said third transistor, and said step of applying said second supply voltage to said second storage node comprises activating said fourth transistor.

20. The method of claim 17, wherein said at least one memory cell further comprises a fifth transistor coupled between said first and second storage nodes, the method further comprising activating said fifth transistor between the programming phases of the first and second resistance switching elements.
